(19) United States
(12) Patent Application Publication
(10) Pub. No.: US 2026/0047451 A1
(43) Pub. Date: Feb. 12, 2026

(54) SEMICONDUCTOR PACKAGE, POWER ELECTRONIC SYSTEM AND METHOD FOR COUPLING A SEMICONDUCTOR PACKAGE TO A HEATSINK

(71) Applicant: Infineon Technologies AG, Neubiberg (DE)

(72) Inventors: Arthur Unrau, Geseke (DE); Florian Berger, Bad Abbach (DE); Michael Fügl, Neumarkt (DE); Johann Gatterbauer, Parsberg (DE); Andreas Grassmann, Sinzing (DE); Paul Schwarzfischer, Regensburg (DE)

(21) Appl. No.: 19/277,825

(22) Filed: Jul. 23, 2025

(30) Foreign Application Priority Data
Aug. 7, 2024 (DE) 102024207485.3
Nov. 8, 2024 (DE) 102024210753.0

(51) Int. Cl. H01L 23/495; H01L 21/48; H01L 21/56; H01L 23/00; H01L 23/31; H01L 23/40; H01L 25/07; H10D 80/00

(52) U.S. Cl. CPC H01L 23/49562; H01L 21/4821; H01L 21/4875; H01L 21/565; H01L 23/40; H01L 23/3121; H01L 2023/405; H01L 2023/4081; H01L 23/49534; H01L 24/32; H01L 24/83; H01L 25/072; H01L 2224/32225; H01L 2224/8384; H10D 80/00

(57) ABSTRACT

A semiconductor package includes: a molded body having opposite first and second sides; at least one semiconductor die encapsulated by the molded body; and a die carrier having opposite first and second sides. The semiconductor die is arranged over the first side of the die carrier. The second side of the die carrier is at least partially exposed from the second side of the molded body, forming at least one exposed portion of the die carrier. The first side of the molded body includes a first portion protruding from a second portion in a vertical direction perpendicular to the first side, forming a planar surface. The second portion extends completely along at least one edge of the first side. A center point of the first portion is in vertical alignment with a center point of the exposed portion.

### TECHNICAL FIELD

The present disclosure in general relates to a semiconductor package, in particular a semiconductor package, wherein a first portion of a first side of a molded body vertically protrudes from a second portion, as well as to a power electronic system comprising a semiconductor package and a heatsink and to a method for coupling a semiconductor package to a heatsink.

### BACKGROUND

A semiconductor package may comprise one or more semiconductor dies and a molded body configured to protect the one or more semiconductor dies from environmental influences. Such a semiconductor package may be configured to be coupled to a heatsink configured to dissipate heat generated by the one or more semiconductor dies during operation. Such a coupling may for example be done by sintering, soldering, clamping or screwing the semiconductor package to the heatsink. However, fabrication tolerances may cause the semiconductor package to become tilted with respect to the heatsink during the coupling process which could lead to unsatisfactory thermal and/or mechanical properties of the coupling. Furthermore, pressure exerted onto the semiconductor package during the coupling process may cause damage if too much pressure is exerted onto certain parts of the semiconductor package, for example onto an edge region of the semiconductor package. Improved semiconductor packages, improved power electronic systems comprising a semiconductor package and improved methods for coupling a semiconductor package to a heatsink may help with solving these and other problems.

### SUMMARY

Various aspects pertain to a semiconductor package, comprising: a molded body comprising a first side and an opposite second side, at least one semiconductor die encapsulated by the molded body, and a die carrier comprising a first side and an opposite second side, wherein the at least one semiconductor die is arranged over the first side of the die carrier and wherein the second side of the die carrier is at least partially exposed from the second side of the molded body, forming at least one exposed portion of the die carrier, wherein the first side of the molded body comprises a first portion and a second portion, wherein the first portion protrudes from the second portion in a vertical direction, forming a planar surface, wherein the vertical direction is perpendicular to the first side, wherein the second portion extends completely along at least one edge of the first side, and wherein a center point of the first portion is in vertical alignment with a center point of the exposed portion.

Various aspects pertain to a power electronic system, comprising: a semiconductor package as described above and a heatsink, wherein the semiconductor package is mechanically coupled to the heatsink such that the second side of the semiconductor package faces the heatsink.

Various aspects pertain to a method for mechanically coupling a semiconductor package to a heatsink, the method comprising: providing a semiconductor package comprising: a molded body comprising a first side and an opposite second side, at least one semiconductor die encapsulated by the molded body, and a die carrier comprising a first side and an opposite second side, wherein the at least one semiconductor die is arranged over the first side of the die carrier and wherein the second side of the die carrier is at least partially exposed from the second side of the molded body, forming at least one exposed portion of the die carrier, wherein the first side of the molded body comprises a first portion and a second portion, wherein the first portion protrudes from the second portion in a vertical direction, forming a planar surface, wherein the vertical direction is perpendicular to the first side, wherein the second portion extends completely along at least one edge of the first side, and wherein a center point of the first portion is in vertical alignment with a center point of the exposed portion; arranging the semiconductor package over a heatsink such that the second side of the semiconductor package faces the heatsink; and exerting pressure onto the first portion but not onto the second portion of the first side of the molded body in order to mechanically and thermally couple the semiconductor package to the heatsink.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a sectional view of a semiconductor package, wherein a first side of a molded body comprises a first portion which vertically protrudes from a second portion of the first side.

FIG. 2 illustrates a sectional view of the semiconductor package of FIG. 1 being coupled to a heatsink using a press. The press exerts pressure onto the first portion of the first side of the molded body but not onto the second portion.

FIGS. 3A to 3C show a further exemplary semiconductor package comprising a molded body with the first portion and the second portion.

FIGS. 4A to 4D show a power electronic system comprising a semiconductor package which is coupled to a substrate via clamps (FIGS. 4A and 4B), via screws (FIG. 4C) and via a sintered layer (FIG. 4D).

FIG. 5 is a flow chart of an exemplary method for coupling a semiconductor package to a heatsink.

FIG. 6 shows a further exemplary semiconductor package comprising a molded body with a first portion comprising separated islands.

FIG. 7 illustrates a sectional view of the semiconductor package of FIG. 6 being coupled to a heatsink using a press. The press exerts different pressures on the islands of the first portion.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary”is merely meant as an example, rather than the best or optimal.

In several examples layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

An efficient semiconductor package, an efficient power electronic system and an efficient method for coupling a semiconductor package to a substrate like a heatsink may for example reduce material consumption, ohmic losses, chemical waste, etc. and may thus enable energy and/or resource savings. Improved semiconductor packages improved power electronic systems and improved methods for coupling a semiconductor package to a substrate like a heatsink, as specified in this description, may thus at least indirectly contribute to green technology solutions, i.e. climate-friendly solutions providing a mitigation of energy and/or resource use.

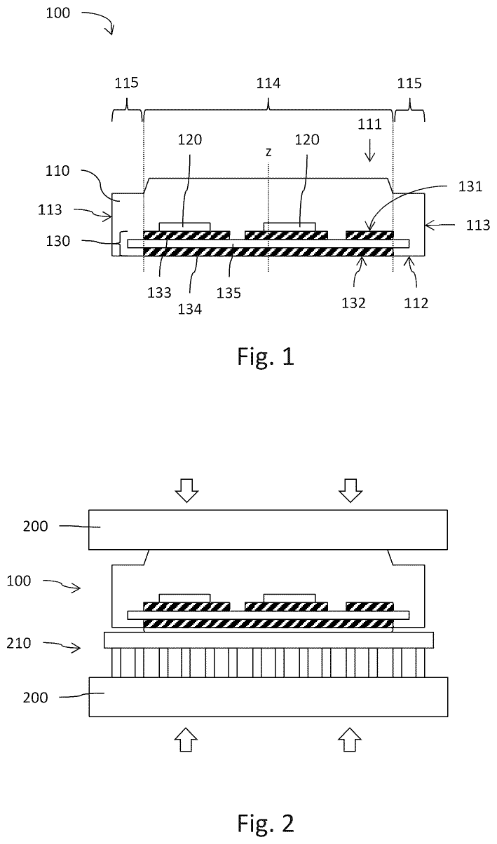

FIG. 1 shows a sectional view of a semiconductor package 100 comprising a molded body 110, at least one semiconductor die 120 and a die carrier 130. The semiconductor package 100 may for example be a power semiconductor package, configured to operate with a high voltage, e.g. a voltage of 100V or more, or 200V or more, or 500V or more, or 1 kV or more, and/or a strong electrical current, e.g. a current of 1 A or more, or 10 A or more, or 100 A or more. The semiconductor package 100 may be configured to be used in any suitable application, e.g. in automotive applications, industrial applications, household applications, etc.

The semiconductor package 100 may comprise any suitable electrical circuit or the semiconductor package 100 may be configured to be part of any suitable electrical circuit. For example, the semiconductor package 100 may comprise a half bridge circuit, a full bridge circuit, a converter circuit, an inverter circuit, etc.

The molded body 110 comprises a first side 111 and an opposite second side 112. The molded body 110 may furthermore comprise lateral sides 113 connecting the first and second sides 111, 112. The molded body 110 may have any suitable shape and any suitable dimensions. For example, the molded body 110 may have an essentially rectangular or quadratic shape as viewed from above the first side 111. According to an example, the first and second sides 111, 112 may have identical or essentially identical shapes and/or sizes. The first and second sides 111, 112 may be those sides of the molded body 110 which have the largest surface area of any of the sides of the molded body 110.

The molded body 110 may be fabricated using any suitable fabrication process, for example compression molding, injection molding or transfer molding. The molded body 110 may comprise or consist of any suitable mold material. According to an example, the molded body 110 may also comprise inorganic filler particles configured to reduce the thermal resistance of the molded body 110.

The at least one semiconductor die 120 is encapsulated by the molded body 110. The molded body 110 may be configured to protect the at least one semiconductor die 120 from environmental influences. The at least one semiconductor die 120 may be any suitable type of semiconductor die, for example a power semiconductor die. The at least one semiconductor die 120 may for example comprise a vertical transistor structure or a lateral transistor structure.

In the example shown in FIG. 1, the semiconductor package 100 comprises two semiconductor dies 120. However, the semiconductor package 100 may comprise any suitable number of semiconductor dies 120, for example one, two, four, six, etc. Furthermore, the more than one semiconductor dies 120 may all be the same type of die or different types of dies. Note that for the sake of simplicity, no internal electrical connections of the semiconductor package 100 are shown in FIG. 1.

The die carrier 130 comprises a first side 131 and an opposite second side 132. The at least one semiconductor die 120 is arranged over the first side 131 of the die carrier 130. Furthermore, the second side 132 of the die carrier 130 is at least partially exposed from the second side 112 of the molded body 110. In other words, the die carrier 130 may comprise at least one exposed portion which is not covered by the molded body 110.

The at least one exposed portion of the die carrier 130 may be configured to be mechanically and thermally connected to a heatsink and/or a baseplate. Such a connection may for example comprise sintering, soldering, screwing or clamping the semiconductor package 100 to the heatsink and/or to the baseplate.

In the example shown in FIG. 1, the die carrier 130 comprises a single exposed portion. However, the die carrier 130 may comprise any suitable number of exposed portions, for example one, two, three, four, etc. The exposed portions may for example be arranged in a line, in a matrix, etc. on the second side 112 of the molded body 110.

The die carrier 130 may be any suitable type of die carrier, for example a direct copper bond (DCB), a direct aluminum bond (DAB), an active metal braze (AMB), an insulated metal substrate (IMS), a printed circuit board (PCB), a leadframe, etc. The die carrier 130 may for example be a power electronics substrate. The die carrier 130 may for example comprise two electrically conductive layers 133, 134 separated from each other by an electrically insulating layer 135.

As shown in FIG. 1, the first side 111 of the molded body 110 comprises a first portion 114 and a second portion 115. The first portion 114 protrudes from the second portion 115 in a vertical direction, wherein the vertical direction is perpendicular to the first side 111. Furthermore, the first portion 114 forms a planar surface. The planar surface may be parallel to the second side 132 of the die carrier 130, in particular parallel to the exposed portion of the die carrier 130.

In the example shown in FIG. 1, the first side 111 comprises a slope between the planar surface of the first portion 114 and the second portion 115. This slope may for example be arranged at an angle in the range of about 30° to slightly less than 90° with respect to the planar surface. However, it is also possible that the first side 111 comprises a vertical step between the first portion 114 and the second portion 115.

The semiconductor package 100 may comprise external contacts which may for example be exposed from one or more of the lateral sides 113 and/or the first side 111 of the molded body 110 (not shown in FIG. 1). The external contacts may for example be power contacts, e.g. direct current contacts and one or more phase current contacts as well as control contacts, sensing contacts, etc. The power contacts may for example be exposed from one or more of the lateral sides 113 and the control or sensing contacts may for example be exposed from the first side 111, in particular the first region 114 and/or the second region 115. Power contacts may, for example, comprise or consist of metal clips. Control or sensing contacts may for example comprise or consist of pins.

The semiconductor package 100 may have any suitable dimensions and any suitable shape. For example, the semiconductor package may have an essentially quadratic or rectangular shape as viewed from above the first side 111. The semiconductor package 100 may for example have edge lengths as viewed from above the first side 111 in the range of about 5 mm to about 10 cm. The first portion 114 may for example constitute about 30% or more, or about 50% or more, or about 70% or more, or about 90% or more of the surface area of the first side 111.

The second portion 115 extends completely along at least one edge of the first side 111 (or in other words, along one of the lateral sides 113 of the molded body 110). The second portion 115 may also extend completely along two edges of the first side 111 (e.g. along two opposite edges) or along three edges or along all four edges of the first side 111. In other words, it is possible that the first portion 114 is completely surrounded by the second portion 115.

Furthermore, a center point of the first portion 114 is in vertical alignment with a center point of the exposed portion of the die carrier 130. This is indicated in FIG. 1 by the vertical line z. In the case that the exposed portion of the die carrier 130 is the center of the die carrier 130, the center point of the first portion 114 is in vertical alignment with a center point of the die carrier 130 as a whole. In this regard, the “center point” is the center of the surface area of the first portion 114, respectively the exposed portion, as viewed from above the first portion 114, respectively from below the exposed portion of the die carrier 130.

According to the example shown in FIG. 1, the first portion 114 is arranged inside a circumference of the at least one exposed portion of the die carrier 130 and the second portion 115 is at least partially arranged outside of the circumference of the exposed portion. This is indicated in FIG. 1 by the two dashed lines between the first portion 114 and the second portion 115. According to an example, at least 50% of the second portion 115 is arranged outside of the circumference of the exposed portion of the die carrier 130.

In the example shown in FIG. 1, the circumference of the exposed portion of the die carrier 130 and a circumference of the first portion 114 of the first side 111 of the molded body 110 are essentially in perfect alignment. According to another example, the exposed portion of the die carrier 130 may be smaller than the first portion 114 such that the circumference of the exposed portion is arranged laterally inside of the circumference of the first portion 114. According to yet another example, it is the other way around. However, in either case the center points of the first portion 114 and of the exposed portion of the die carrier 130 are in vertical alignment along the line z.

The above-described arrangement of the first portion 114 and the exposed portion of the die carrier 130 relative to each other may have the following benefits: as mentioned above, the semiconductor package 100 may be configured to be connected to a substrate like a heatsink and/or a baseplate such that the second side 112 of the molded body 110 faces the substrate. Connecting the semiconductor package 100 to the substrate may comprise exerting pressure onto the first side 111 of the molded body 110 and onto the substrate (and thereby onto the exposed portion of the die carrier 130). An example of such a connecting process is shown in FIG. 2, wherein the semiconductor package 100 and a substrate 210 are arranged in a press 200. As shown in FIG. 2, pressure is exerted onto the first portion 114 but not onto the second portion 115 of the first side 111 of the molded body 110. Since the first portion 114 is in vertical alignment with the exposed portion of the die carrier 130 as described further above, pressure may be distributed evenly across the exposed portion of the die carrier 130. For this reason, it may be possible to fabricate a joint (e.g. a sintered joint) of homogeneous thickness between the semiconductor package 100 and the substrate 210.

If the first portion 114 was absent, i.e. if the first side 111 of the molded body 110 was flat, a higher pressure could be exerted onto one edge region of the first side 111 than onto an opposite second edge region due to alignment tolerances between the semiconductor package 100 and the substrate 210 on the one hand and the press 200 on the other hand. This could for example create a tilted joint between the semiconductor package 100 and the substrate 210 and/or this could lead to the fabrication of a defective joint. In other words, the protruding first portion 114 which is aligned with the exposed portion of the die carrier 130 may help with fabricating a joint of uniform thickness. This may, for example, improve the thermal and/or mechanical characteristics of such a joint.

The above-described alignment between the first portion 114 and the exposed portion of the die carrier 130 may have a further benefit: as shown in the example of FIG. 1, the die carrier 130 may comprise the insulating layer 135 which may laterally protrude from the conductive layers 133, 134. The insulating layer 135 may, for example, comprise or consist of a ceramic layer and may be comparatively brittle. If the press 200 would exert pressure onto the second region 115, the insulating layer 135 could crack in the case that this pressure becomes too high. The configuration of the semiconductor package 100 with the first portion 114 and the second portion 115 as described above, however, may prevent such cracks from occurring.

The first portion 114 may protrude from the second portion 115 by any suitable height as long as the above-mentioned effects are obtained. For example, the first portion 114 may protrude by about 50 μm or more, or about 100 μm or more, or about 150 μm or more, or about 300 μm or more, or about 500 μm or more.

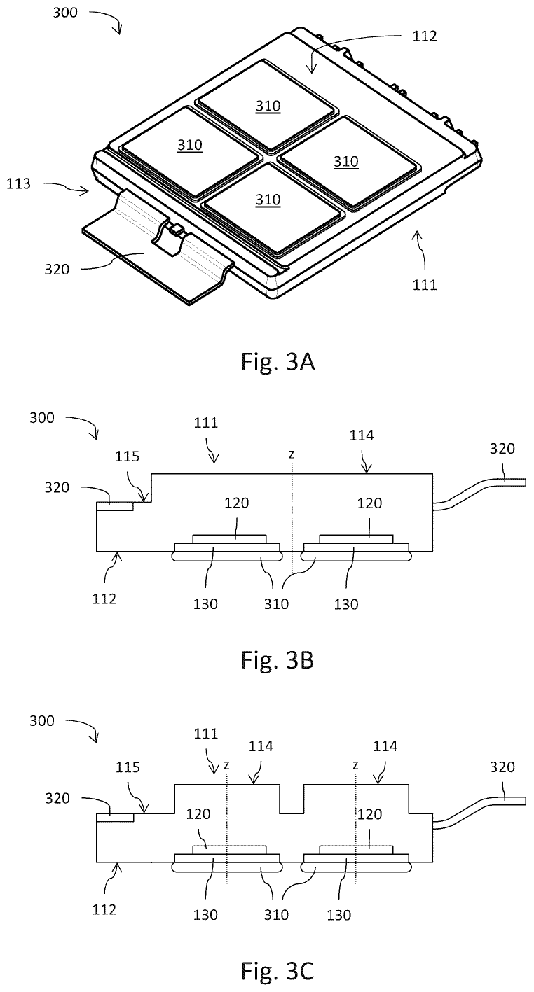

FIG. 3A shows a perspective view of a semiconductor package 300 which may be similar or identical to the semiconductor package 100, except for the differences described in the following. Note that in FIG. 3A the semiconductor package 300 is shown with the second side 112 of the molded body 110 pointing up and the first side 111 pointing down.

The semiconductor package 300 may for example be configured to be connected to a substrate like a heatsink or a baseplate via a sintered joint. In order to fabricate such a joint, sintering material 310 is deposited over the exposed portion of the die carrier(s) 130 exposed from the second side 112 of the molded body 110. Note that in the example shown in FIG. 3A, the semiconductor package 300 comprises four exposed portions of the die carrier(s) 130 which are arranged in a matrix. The four exposed portions shown in FIG. 3A have equal shapes and equal sizes. However, it is also possible that the exposed portions have different shapes and/or different sizes.

The semiconductor package 300 may comprise an external contact 320 arranged at one of the lateral sides 113 of the molded body 110. The semiconductor package 300 may comprise further external contacts 320 which may for example be arranged at the same lateral side 113 as the external contact 320 and/or at the opposite lateral side 113. The further external contacts 320 may for example be exposed from the second portion 115 of the first side 111 (compare FIGS. 3B and 3C).

The semiconductor package 300 may have an asymmetrical configuration as viewed from above the second side 112 of the molded body 110. This may mean that the exposed portions of the die carrier(s) 130 and therefore the deposits of sintering material 310 are not centered on the second side 112 (in FIG. 3A, the exposed portions and therefore the deposits of sintering material 310 are arranged closer to the left edge than to the right edge of the second side 112). For this reason, if the first side 111 did not comprise a protruding first portion 114 aligned with the deposits of sintering material 310, the press 200 could exert pressure on the whole first side 111 during a sintering process (compare FIG. 2). In this case, the sintering material 310 would be pressed down more strongly at one edge of the first side 111 than at the opposite edge of the first side 111.

FIG. 3B shows a sectional view of the semiconductor package 300. As shown in FIG. 3B, the first portion 114 of the first side 111 is in vertical alignment with the exposed portions of the die carriers 130 and therefore also with the deposits of sintering material 310. This may mean that a center point of the first side 111 and a common center point of the exposed portions of the die carriers 130 are both arranged along the vertical line z. Furthermore, the exposed portions of the die carriers 130 may for example be arranged within a circumference of the first portion 114 (compare FIG. 3B). According to another example, it is the other way around.

FIG. 3C shows a sectional view of the semiconductor package 300 according to a further example which is similar or identical to the example shown in FIG. 3B, except for the differences described in the following. In particular, in the example shown in FIG. 3C, the first side 111 comprises a plurality of first portions 114 which are in vertical alignment with the plurality of exposed portions of the die carriers 130. For example, there may be a first portion 114 aligned with each individual exposed portion of the die carriers 130 or two or more of the exposed portions may be aligned with a common first portion 114.

Since the second portion 115 and not the first portion 114 is arranged vertically above the specific part of the second side 112 that does not comprise any exposed portions of the die carriers 130, the semiconductor package 300 does not get tilted by the press 200 and sintered joints of homogenous thickness may be fabricated.

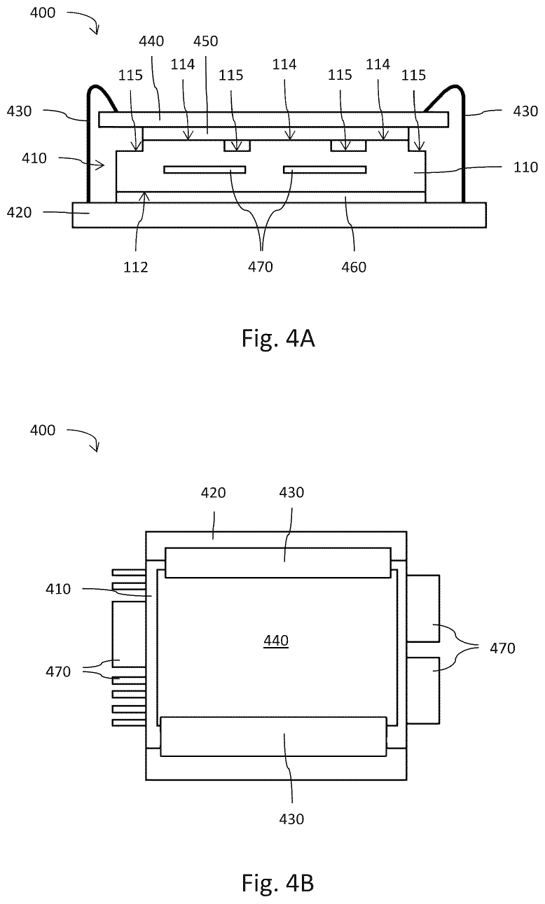

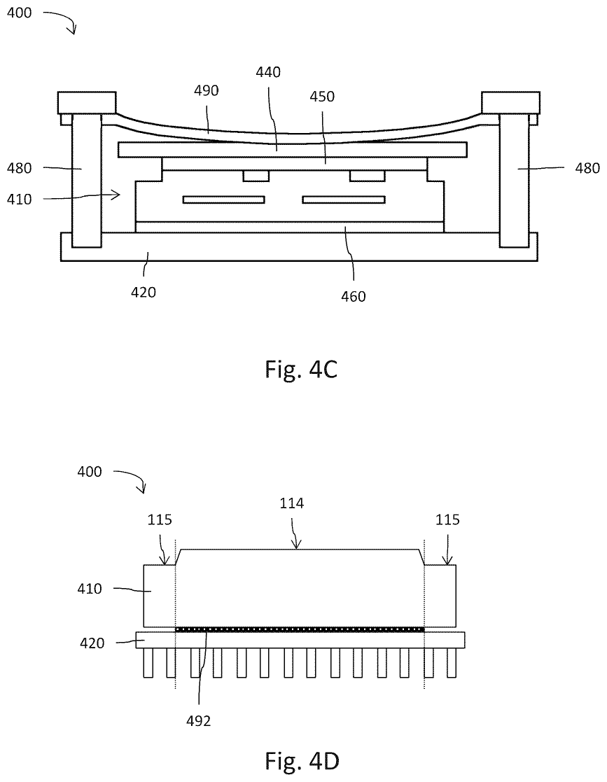

FIG. 4A shows a sectional view of a power electronic system 400. The power electronic system 400 comprises a semiconductor package 410 mounted on a substrate 420. The semiconductor package 410 may be similar or identical to the semiconductor package 100 or 300. The substrate 420 may for example be a heatsink and/or a baseplate. The semiconductor package 410 is arranged over the substrate 420 such that the second side 112 of the molded body 110 faces the substrate 420. In the example shown in FIG. 4A, the first side 111 of the molded body 110 comprises a plurality of first portions 114. However, the first side 111 may of course also comprise only a single first portion 114.

The semiconductor package 410 is mechanically coupled to the substrate 420 by clamps 430 exerting pressure onto the first portion(s) 114 of the first side 111 of the molded body 110. The clamps 430 may for example be metal clamps and may for example be arranged at opposite lateral sides of the semiconductor package 410. Since the semiconductor package 410 is mechanically fixed to the substrate 420 by the clamps, it may not be necessary to also solder or sinter the semiconductor package 410 to the substrate 410.

According to an example, the power electronic system 400 comprises a rigid plate 440 connected between the clamps 430 and the semiconductor package 410. The rigid plate 440 may be configured to distribute the mechanical force exerted by the clamps 430 onto the semiconductor package 410 over the first portion(s) 114 of the first side 111 of the molded body 110. The rigid plate 440 may for example be a metal plate.

According to an example, the power electronic system 400 further comprises an elastic layer 450 arranged between the rigid plate 440 and the first portion(s) 114 of the first side 111 of the molded body 110. The elastic layer 450 may be configured to homogenously distribute pressure across the first portion(s) 114 and/or to compensate for height tolerances. The elastic layer 450 may comprise or consist of any suitable elastic material and may for example comprise or consist of a rubber mat. According to another example, the power electronic system 400 does not comprise the elastic layer 450, meaning that the rigid plate 440 directly contacts the first portion(s) 114.

The power electronic system 400 may further comprise an electrically insulating layer 460 arranged between the semiconductor package 410 and the substrate 420 and configured to electrically insulate the semiconductor package 410 from the substrate 420.

FIG. 4B shows a plan view of the power electronic system 400 from above the rigid plate 440. As shown in FIG. 4B, the clamps 430 may, for example, be arranged at two opposite lateral sides of the semiconductor package 410 and the remaining two lateral sides of the semiconductor package 410 may comprise external contacts 470.

The first portion(s) 114 of the first side 111 of the molded body 110 may for example be arranged at a non-zero distance from the edges of the first side 111. The reason for such an arrangement may be that exerting pressure onto the edges could lead to severe warpage of the semiconductor package 410 and such a warpage could potentially damage the semiconductor package 410. The first portion(s) 114 may therefore be arranged on the first side 111 in such positions that severe warpage of the semiconductor package 410 may be avoided.

FIG. 4C shows the power electronic system 400 according to a further example. In particular, in the example shown in FIG. 4C, the clamps 430 are replaced by screws 480. In the example shown in FIG. 4C, a spring element 490 is arranged between the screws 480 and the rigid plate 440, wherein the spring element 490 is configured to exert pressure onto the rigid plate 440. According to another example, the screws 480 are directly connected to the rigid plate 440.

FIG. 4D shows the power electronic system 400 according to yet a further example. In FIGS. 4A-4C the semiconductor package 410 is coupled to the substrate 420 in a reversible manner using clamps or screws. In the example shown in FIG. 4D on the other hand, the semiconductor package 410 is sintered onto the substrate 420 via a sintered layer 492. As shown in FIG. 4D, the sintered layer 492 may be arranged within a circumference of the first portion 114. Furthermore, a space between the semiconductor package 410 and the substrate 420 below the second portion 115 may be free of the sintered layer 492.

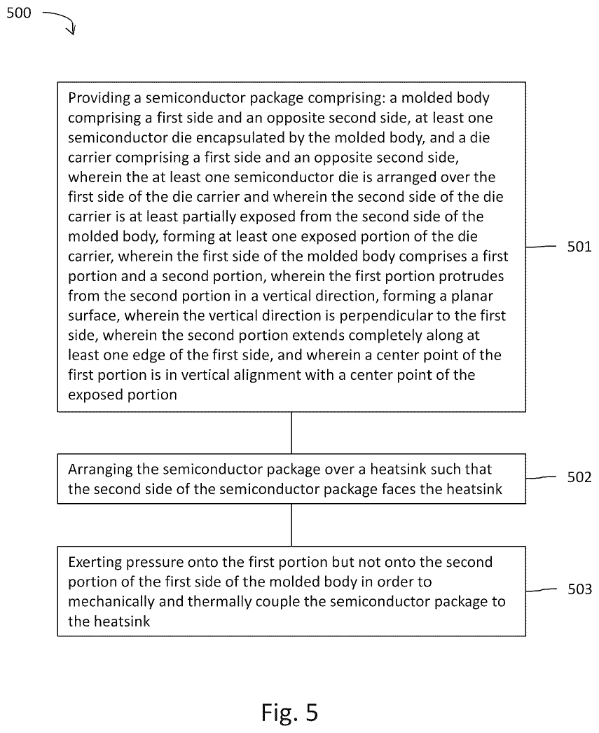

FIG. 5 is a flow chart of an exemplary method 500 for mechanically coupling a semiconductor package to a heatsink. The method 500 may for example be used to couple one of the semiconductor packages 100, 300 and 400 to the substrate 200 or 420.

The method 500 comprises at 501 a process of providing a semiconductor package comprising: a molded body comprising a first side and an opposite second side, at least one semiconductor die encapsulated by the molded body, and a die carrier comprising a first side and an opposite second side, wherein the at least one semiconductor die is arranged over the first side of the die carrier and wherein the second side of the die carrier is at least partially exposed from the second side of the molded body, forming at least one exposed portion of the die carrier, wherein the first side of the molded body comprises a first portion and a second portion, wherein the first portion protrudes from the second portion in a vertical direction, forming a planar surface, wherein the vertical direction is perpendicular to the first side, wherein the second portion extends completely along at least one edge of the first side, and wherein a center point of the first portion is in vertical alignment with a center point of the exposed portion. The method 500 comprises at 502 a process of arranging the semiconductor package over a heatsink such that the second side of the semiconductor package faces the heatsink and at 503 a process of exerting pressure onto the first portion but not onto the second portion of the first side of the molded body in order to mechanically and thermally couple the semiconductor package to the heatsink.

According to an example of the method 500, coupling the semiconductor package to the heatsink comprises a sintering process. According to another example, coupling the semiconductor package to the heatsink comprises a clamping process or a screwing process.

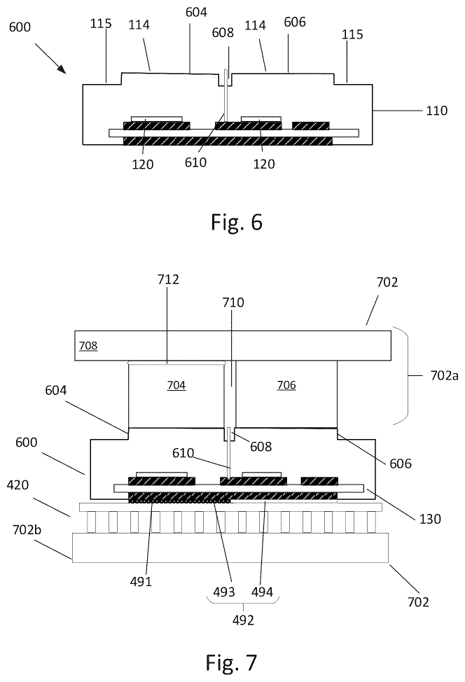

FIG. 6 shows a sectional view of a semiconductor package 600 which may be similar or identical to the semiconductor package 100, 300, 410 except for the differences described in the following. The semiconductor package 600 is shown with a recess 608 in the first portion 114 of the molded body 110. The first portion 114 has two separate islands, e.g., a first island 604 and a second island 606 separated from each other by the recess 608. The recess 608 can be formed by a protrusion in the mold tool or by dicing e.g. laser dicing, etching. As an example, the semiconductor package 600 as shown in FIG. 6 has two islands separated by one recess. However, the semiconductor package 600 may have more than two islands and more than one recess. The semiconductor package may also have an external contact, such as but not limited to a press-fit pin 610, protruding from the recess 608. The contact may be electrically coupled with the semiconductor die 120, either directly or via the die carrier 130, e.g. an upper conductive layer 133.

When mounting a semiconductor package 600 onto the substrate 420 using a sinter press it may be desirable to exert different pressure to different portions of the semiconductor package. For instance, regions of the semiconductor package with quite a lot of stiff material, semiconductor dies or metal contacts such as press fit pins, may transfer pressure for the sinter press different from the surrounding mold compound. The overall maximum pressure applied by the sinter press may thus be limited by specific parts of the semiconductor package. The recesses in the mold package may spare some areas from being exerted the overall pressure limitation which would still be present.

FIG. 7 shows another example of the connecting process of the semiconductor package 600 with the substrate 420 in which the pressure of a sinter press 702 can be optimized further. The semiconductor package 600 and the substrate 420, e.g. a baseplate or a cooler, are arranged in the sinter press 702. The sinter layer 491, e.g. a sinter paste, is arranged between the exposed portion of the die carrier 130 and the substrate 420. The sinter press 702 has an upper section 702a facing the first portion 114 and a lower section 702b facing the substrate 420. The upper section 702a has a first independent segment 704 and a second independent segment 706 mounted on a head 708. The independent segments 704, 706 are separated from each other by a gap 710. The upper section 702a is arranged such that the first independent segment 704 faces the first island 604, the second independent segment 706 faces the second island 606 and the gap 710 faces the recess 608 of the first portion 114. The islands 604 and 606 may now be pressed with different forces applied by the upper section 702a of the sinter press 702, respectively. An O-ring 712 comprising an elastic material may be arranged between the head 708 and the first independent segment 704 as shown in FIG. 7. When the upper section 702a presses the first section 114, the O-ring 712 is deformed and reduces the force exerted on the first island 604 as compared to the second island 606. In particular, the first independent segment 704 is configured to press the first island 604 with a first force and the second independent segment 706 is configured to press the second island 606 with a second force which may be different from the first force. Due to the O-ring 712 in the sinter press 702, the first force is less than the second force. Therefore, a pressure will be non-uniformly distributed across the exposed portion of the die carrier 130. Consequently, the sinter layer 491 will also experience the non-uniform pressure. The sinter layer 491 may have a thickness in a range of 15 to 500 um, in particular 30 to 300 μm, measured vertically between the exposed portion of the die carrier 130 and the substrate 420. Due to the few μm thickness of the sinter layer 491, the non-uniform pressure will lead to different porosities in the final sintered layer 492. In particular, since a first part 493 of the sinter layer 491 below the first island 604 will experience less pressure than a second part 494 of the sinter layer 491 below the second island 606, the joint formed in the first part 493 of the sintered layer 492 will have higher porosity than the joint formed in the second part 494 of the sintered layer 492. Higher porosity implies that particles e.g. silver particles in the first part 493 of the joint are separated by a larger distance as compared to particles in the second part 494 of the joint. The first part 493 may have more voids as compared to the second part 494. The difference in the porosity depends on the difference in the pressure and may be in the range of 2 - 50%, in particular 5-30%. The non-uniform porosity of the joint increases the flexibility of the joint without changing the mechanical strength of the joint.

The pressing of the first section 114 may be achieved by different methods. For example, the upper section 702a may be a chamber comprising a gas e.g., nitrogen for pressing. The gas may be distributed in the upper section 702a such that the upper section 702a presses the first island 604 with the first force and the second island 606 with the second force.

As described herein above, the gap 710 of the sinter press 702 overlaps with the recess 608 of the first portion 114 and therefore, the sinter press 702 does not exert any force on the recess 608. In case a contact, such as a press-fit pin is inserted into the recess as illustrated in FIG. 6, the semiconductor package 600 can be pressed onto the substrate 420 without damaging the press-fit pin 610 or the below die carrier 130.

In the following, the semiconductor package, the power electronic system and the method for mechanically coupling a semiconductor package to a heatsink are further explained using specific examples.

Example 1 is a semiconductor package, comprising: a molded body comprising a first side and an opposite second side, at least one semiconductor die encapsulated by the molded body, and a die carrier comprising a first side and an opposite second side, wherein the at least one semiconductor die is arranged over the first side of the die carrier and wherein the second side of the die carrier is at least partially exposed from the second side of the molded body, forming at least one exposed portion of the die carrier, wherein the first side of the molded body comprises a first portion and a second portion, wherein the first portion protrudes from the second portion in a vertical direction, forming a planar surface, wherein the vertical direction is perpendicular to the first side, wherein the second portion extends completely along at least one edge of the first side, and wherein a center point of the first portion is in vertical alignment with a center point of the exposed portion.

Example 2 is the semiconductor package of example 1, wherein the second portion extends completely along at least two opposite edges of the first side.

Example 3 is the semiconductor package of example 1, wherein the second portion extends completely along all four edges of the first side.

Example 4 is the semiconductor package of one of the preceding examples, wherein the first portion comprises a plurality of islands separated from each other by the second portion.

Example 5 is the semiconductor package of examples 1 to 3, wherein the first portion has a recess.

Example 6 is the semiconductor package of example 5, further comprising a press-fit pin protruding from the recess.

Example 7 is the semiconductor package of one of the preceding examples, wherein the first portion is arranged inside a circumference of the at least one exposed portion of the die carrier and wherein the second portion is at least partially arranged outside of the circumference of the at least one exposed portion.

Example 8 is the semiconductor package of example 7, wherein at least 50% of the second portion is arranged outside of the circumference.

Example 9 is the semiconductor package of one of the preceding examples, further comprising: power contacts electrically connected to power terminals of the at least one power semiconductor die, wherein the power contacts are exposed from the second portion of the first side of the molded body.

Example 10 is the semiconductor package of one of the preceding examples, wherein the die carrier comprises or consists of a leadframe or a substrate comprising two electrically conductive layers separated by an electrically insulating layer.

Example 11 is the semiconductor package of example 10, wherein the die carrier comprises two metal layers separated by a ceramic layer, wherein a protrusion portion of the ceramic layer laterally protrudes from the metal layers, the lateral direction being parallel to the first and second sides of the die carrier, and wherein a part of the first side of the molded body vertically above the protrusion portion consists of the second portion.

Example 12 is a power electronic system, comprising: a semiconductor package according to one of the preceding claims, and a heatsink, wherein the semiconductor package is mechanically coupled to the heatsink such that the second side of the semiconductor package faces the heatsink.

Example 13 is the power electronic system of example 12, wherein the second side of the die carrier is connected to the heatsink by a sintered layer.

Example 14 is the power electronic system of example 13, wherein the sintered layer is arranged within a circumference of the first portion.

Example 15 is the power electronic system of example 13 or 14, wherein a space vertically below the second portion is free of the sintered layer.

Example 16 is the power electronic system of example 14, wherein the semiconductor package is mechanically coupled to the heatsink by clamps or screws exerting pressure onto the first portion of the first side of the molded body.

Example 17 is the power electronic system of example 16, further comprising: a rigid plate connected between the clamps or screws and the semiconductor package, and an elastic layer arranged between the rigid plate and the first portion of the first side of the molded body and configured to homogenously distribute pressure along the first portion.

Example 18 is a method for mechanically coupling a semiconductor package to a heatsink, the method comprising: providing a semiconductor package comprising: a molded body comprising a first side and an opposite second side, at least one semiconductor die encapsulated by the molded body, and a die carrier comprising a first side and an opposite second side, wherein the at least one semiconductor die is arranged over the first side of the die carrier and wherein the second side of the die carrier is at least partially exposed from the second side of the molded body, forming at least one exposed portion of the die carrier, wherein the first side of the molded body comprises a first portion and a second portion, wherein the first portion protrudes from the second portion in a vertical direction, forming a planar surface, wherein the vertical direction is perpendicular to the first side, wherein the second portion extends completely along at least one edge of the first side, and wherein a center point of the first portion is in vertical alignment with a center point of the exposed portion; arranging the semiconductor package over a heatsink such that the second side of the semiconductor package faces the heatsink; and exerting pressure onto the first portion but not onto the second portion of the first side of the molded body in order to mechanically and thermally couple the semiconductor package to the heatsink.

Example 19 is the method of example 18, wherein coupling the semiconductor package to the heatsink comprises a sintering process.

Example 20 is the method of example 19, further comprising: forming a recess in the first portion forming a first and a second island separated from each other and wherein exerting pressure onto the first portion comprises pressing the first portion by a press comprising two independent segments, wherein a first independent segment of the press is pressing onto the first island of the first portion with a first force and a second independent segment of the press is pressing onto the second island of the first portion with a second force.

Example 21 is the method of example 20, the first force is different than the second force.

Example 22 is the method of example 18, wherein coupling the semiconductor package to the heatsink comprises a clamping process or a screwing process.

Example 23 is an apparatus comprising means for performing the method according to anyone of examples 18 to 22.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor package, comprising:
a molded body comprising a first side and an opposite second side;
at least one semiconductor die encapsulated by the molded body; and
a die carrier comprising a first side and an opposite second side,
wherein the at least one semiconductor die is arranged over the first side of the die carrier,
wherein the second side of the die carrier is at least partially exposed from the second side of the molded body, forming at least one exposed portion of the die carrier,
wherein the first side of the molded body comprises a first portion and a second portion,
wherein the first portion protrudes from the second portion in a vertical direction, forming a planar surface,
wherein the vertical direction is perpendicular to the first side,
wherein the second portion extends completely along at least one edge of the first side,
wherein a center point of the first portion is in vertical alignment with a center point of the exposed portion.

2. The semiconductor package of claim 1, wherein the second portion extends completely along at least two opposite edges of the first side.

3. The semiconductor package of claim 1, wherein the second portion extends completely along all four edges of the first side.

4. The semiconductor package of claim 1, wherein the first portion comprises a plurality of islands separated from each other by the second portion.

5. The semiconductor package of claim 1, wherein the first portion has a recess.

6. The semiconductor package of claim 5, further comprising a press-fit pin protruding from the recess.

7. The semiconductor package of claim 1, wherein the first portion is arranged inside a circumference of the at least one exposed portion of the die carrier, and wherein the second portion is at least partially arranged outside of the circumference of the at least one exposed portion.

8. The semiconductor package of claim 7, wherein at least 50% of the second portion is arranged outside of the circumference.

9. The semiconductor package of claim 8, wherein the die carrier comprises two metal layers separated by a ceramic layer, wherein a protrusion portion of the ceramic layer laterally protrudes from the metal layers along a lateral direction that is parallel to the first and second sides of the die carrier, and wherein a part of the first side of the molded body vertically above the protrusion portion consists of the second portion.

10. The semiconductor package of claim 1, further comprising:
a plurality of power contacts electrically connected to a plurality of power terminals of the at least one power semiconductor die,
wherein the power contacts are exposed from the second portion of the first side of the molded body.

11. The semiconductor package of claim 1, wherein the die carrier comprises a leadframe or a substrate comprising two electrically conductive layers separated by an electrically insulating layer.

12. A power electronic system, comprising:
the semiconductor package of claim 1; and
a heatsink to which the semiconductor package is mechanically coupled such that the
second side of the semiconductor package faces the heatsink.

13. The power electronic system of claim 12, wherein the second side of the die carrier is connected to the heatsink by a sintered layer.

14. The power electronic system of claim 13, wherein the sintered layer is arranged within a circumference of the first portion.

15. The power electronic system of claim 13, wherein a space vertically below the second portion is free of the sintered layer.

16. The power electronic system of claim 12, wherein the semiconductor package is mechanically coupled to the heatsink by a plurality of clamps or screws exerting pressure onto the first portion of the first side of the molded body.

17. The power electronic system of claim 16, further comprising:
a rigid plate connected between the clamps or screws and the semiconductor package; and
an elastic layer arranged between the rigid plate and the first portion of the first side of the molded body and configured to homogenously distribute pressure along the first portion.

18. A method for mechanically coupling a semiconductor package to a heatsink, the method comprising:
providing a semiconductor package comprising:
a molded body comprising a first side and an opposite second side;
at least one semiconductor die encapsulated by the molded body; and
a die carrier comprising a first side and an opposite second side, wherein the at least one semiconductor die is arranged over the first side of the die carrier, wherein the second side of the die carrier is at least partially exposed from the second side of the molded body, forming at least one exposed portion of the die carrier, wherein the first side of the molded body comprises a first portion and a second portion, wherein the first portion protrudes from the second portion in a vertical direction, forming a planar surface, wherein the vertical direction is perpendicular to the first side, wherein the second portion extends completely along at least one edge of the first side, wherein a center point of the first portion is in vertical alignment with a center point of the exposed portion;
arranging the semiconductor package over a heatsink such that the second side of the semiconductor package faces the heatsink; and
exerting pressure onto the first portion but not onto the second portion of the first side of the molded body in order to mechanically and thermally couple the semiconductor package to the heatsink.

19. The method of claim 18, wherein coupling the semiconductor package to the heatsink comprises a sintering process.

20. The method of claim 19, further comprising:
forming a recess in the first portion, forming a first and a second island separated from each other,
wherein exerting pressure onto the first portion comprises pressing the first portion by a press comprising two independent segments, wherein a first independent segment of the press presses onto the first island of the first portion with a first force and a second independent segment of the press presses onto the second island of the first portion with a second force.

21. The method of claim 20, wherein the first force is different from the second force.

22. The method of claim 18, wherein coupling the semiconductor package to the heatsink comprises a clamping process or a screwing process.
